(19) United States
(12) Patent Application Publication
(10) Pub. No.: US 2026/0332138 A1
(43) Pub. Date: Oct. 22, 2026

(54) SYSTEM AND METHOD FOR PHASE ALIGNMENT AND CURRENT BALANCING IN A MULTI-PHASE NON-CLOCKED IC

(71) Applicant: MaxLinear, Inc., Carlsbad, CA (US)

(72) Inventor: Glenn Chance Dunlap, III, Houston, TX (US)

(73) Assignee: MaxLinear, Inc., Carlsbad, CA (US)

(21) Appl. No.: 19/653,010

(22) Filed: Apr. 20, 2026

Related U.S. Application Data
(60) Provisional application No. 63/791,149, filed on Apr. 18, 2025.

(51) Int. Cl. H03K 5/131; H03K 5/00; H03K 7/08

(52) U.S. Cl. CPC H03K 5/131; H03K 7/08; H03K 2005/00058

(57) ABSTRACT

A controller may include a voltage regulator, a hysteretic window generator, a phase angle, a phase balance, and a pulse width modulator. The voltage regulator may generate a control signal. The hysteretic window generator may generate, based on the control signal, an upper voltage threshold and a lower voltage threshold. The phase angle may generate phase angle data. The phase balance may receive a total current for multiple phases and generate, based on the total current and the phase angle data, phase balance data. The pulse width modulator may generate, based on the phase balance data, a pulse width modulated signal for a phase of the multiple phases.

### RELATED APPLICATION

This application claims the benefit of U.S. Provisional Application No. 63/791,149, filed Apr. 18, 2025, the disclosure of which is incorporated herein by reference in its entirety.

### FIELD

The examples discussed in the present disclosure are related to phase alignment and current balancing in a multi-phase non-clocked integrated circuit (IC).

### BACKGROUND

Unless otherwise indicated herein, the materials described herein are not prior art to the claims in the present application and are not admitted to be prior art by inclusion in this section.

Power electronics systems may use switching regulators and other circuits to convert, regulate, and deliver electrical power to one or more loads while maintaining selected voltage and current levels. Devices, systems, and methods for enhancing power electronics systems may be useful.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

A controller may include a voltage regulator, a hysteretic window generator, a phase angle, a phase balance, and a pulse width modulator. The voltage regulator may generate a control signal. The hysteretic window generator may generate, based on the control signal, an upper voltage threshold and a lower voltage threshold. The phase angle may generate phase angle data. The phase balance may receive a total current for multiple phases and generate, based on the total current and the phase angle data, phase balance data. The pulse width modulator may generate, based on the phase balance data, a pulse width modulated signal for a phase of the multiple phases. The relative timing for the multiple phases may be controlled using adaptive hysteretic threshold adjustment without using a distributed clock signal.

A system may include multiple phases that may supply current to a load and a controller.

A method may include: receiving an output voltage from multiple phases; generating, based on the output voltage, a control signal; generating, based on the control signal, an upper voltage threshold and a lower voltage threshold; determining a total current for the multiple phases; generating phase angle data; generating, based on the total current and the phase angle data, phase balance data; and generating, based on the phase balance data, a pulse width modulated signal for a phase of the multiple phases.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is noted, however, that the appended drawings illustrate only some aspects of this disclosure and the disclosure may admit to other equally effective examples.

To facilitate understanding, identical reference numerals have been used, where possible, to designate identical elements that are common to the figures. It is contemplated that elements and features of one example may be beneficially incorporated in other examples without further recitation.

FIG. 1 illustrates a schematic of an exemplary switching power supply system, in accordance with some examples;

FIG. 2 illustrates schematic of an exemplary control loop circuit for use in the system shown in FIG. 1, in accordance with some examples;

FIGS. 3A-3B illustrates schematics of an exemplary control loop circuit, in accordance with some examples; and

FIGS. 4A and 4B illustrate a schematic of an exemplary management circuit, in accordance with some examples.

FIG. 5 illustrates a process flow for a control loop circuit.

FIG. 6 illustrates a diagrammatic representation of a machine in the example form of a computing device within which a set of instructions, for causing the machine to perform any one or more of the methods discussed herein, may be executed.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single example, but other examples are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more examples herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Examples described as being implemented in hardware should not be limited thereto, but can include examples implemented in software, or combinations of software and hardware, and vice-versa, as will be apparent to those skilled in the art, unless otherwise specified herein. In the examples described herein, an example showing a singular component should not be considered limiting; rather, the disclosure is intended to encompass other examples including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

The field of power electronics has seen advancements with the advent of digital control in power supply units. Digital control in switching power supplies may allow for management of multiple phases in power conversion processes. Such multiphase digital controllers may synchronize several power stages to efficiently handle high-current demands while reducing thermal stress and electromagnetic interference. This synchronization may enable the power supply to deliver a stable and low-ripple output voltage, which may be used for the reliable operation of sensitive electronic devices and systems. However, many digital switching regulators and controllers lack real-time control with precise phase alignment, and current balancing across the multiple phases.

Some phase alignment approaches in multiphase controllers rely on clocked systems. Such clock systems divide a master clock into multiple phases. However, dividing and distributing a master clock signal introduces complexity in circuit design and limits the flexibility of the system. In environments where conditions rapidly change, such as in the presence of varying loads or fluctuating power supply conditions, the rigidity and delay inherent in clock synchronization may lead to inefficiencies in response times, which may be detrimental in applications having real-time adjustments. Moreover, clocked systems may be susceptible to clock skew and jitter, where small variations in distributed clock signals may cause misalignment in phase timing. Such misalignment may lead to suboptimal power conversion, increased electromagnetic interference, and may even compromise the operational reliability of the system.

The examples described herein relate generally to an advanced digital quad controller (hereinafter “the controller”) that may enhance management in a multiphase power supply system. In some examples, the controller includes a multiphase control loop, which may enhance performance and efficiency in regulating and distributing electrical power. As described in detail below, the controller may intelligently orchestrate activity across multiple power phases to ensure synchronized load sharing and minimize power loss. Such synchronization may reduce ripple and enhance the overall stability of the power supply. The controller may facilitate precision phase alignment and current balancing, enhancing performance and mitigating the potential for phase drift or imbalance.

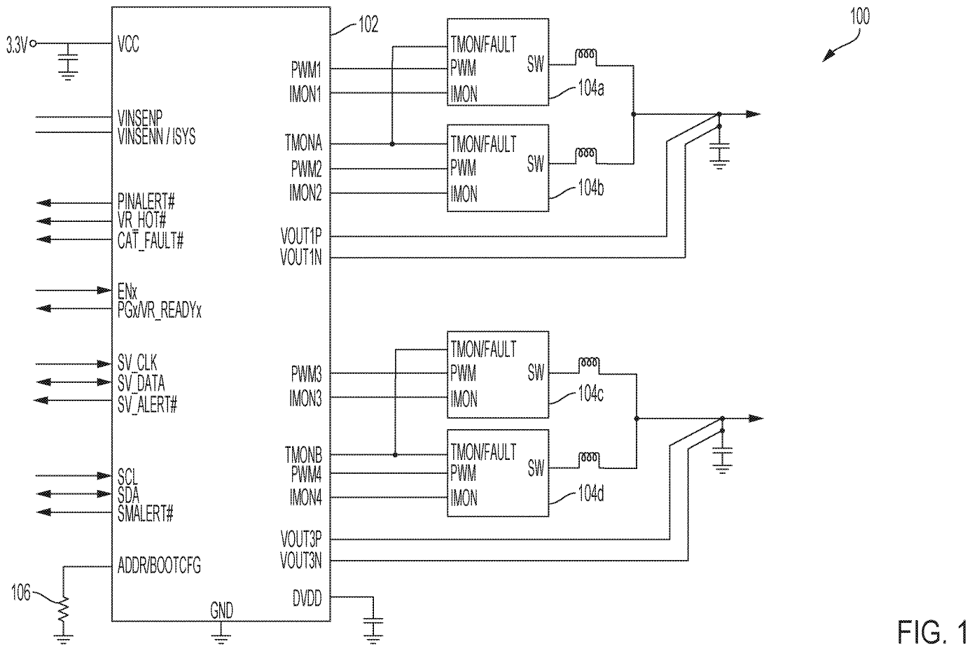

FIG. 1 illustrates a schematic of a Switching Power Supply System 100 (hereinafter “system 100”). In some examples, system 100 may include Multi-Phase Digital Quad Controller 102 (hereinafter “controller 102”), and Switching Power Stage (SPS) 104a, 104b, 104c, 104d. Controller 102 may encompass a communication architecture that maximizes efficiency and power distribution by performance with four Switched Power Supplies (e.g., SPS 104a, 104b, 104c, 104d) within system 100. As shown in FIG. 1, system 100, via controller 102, may efficiently manage and drive up to four outputs simultaneously via SPS 104a, 104b, 104c, 104d. Accordingly, controller 102 may perform logic operations, decision-making, and overall system management, while SPS 104 may encompass individual power conversion units, which controller 102 may manage. Such SPS 104a, 104b, 104c, 104d may, in some examples, be referred to as “phases” in a multiphase power supply system (e.g., 100). In some examples, all or some of, the 4 SPS stages may have different Vin voltages.

Controller 102 may include a design focusing on minimal hardware, reducing setup complexity and time. For example, controller 102 may achieve such minimal hardware, by using resistor 106 for address and configuration settings (ADDR/BOOTCFG), streamlining the hardware setup process. ADDR/BOOTCFG may not only minimize the component count but may also facilitate a more compact and cost-effective design.

In some examples, operational parameters may be governed via software, offering a versatile and user-friendly interface for configuration. Controller 102 software suite may include a graphical user interface (GUI), which may allow for effortless setup and fine-tuning of the device. Such GUI may empower users to adjust settings, monitor performance, and tailor the controller to specific application without the necessity for hardware modifications.

System 100 via controller 102 and SPS 104 may be configured for control and adjustability, offering precision in power regulation. Such software-driven approach may provide the flexibility to adapt to a wide array of operational conditions, ensuring that controller 102 delivers optimal performance across various scenarios. With such level of control, users may expect a responsive system capable of meeting the demands of sophisticated power systems.

As shown in FIG. 1, controller 102 may include various input pins, output pins and/or input/output (I/O) pins. For example, in some examples, controller 102 may include VCC (Voltage Common Collector) pin. Vcc pin may be the main power supply input to controller 102, providing the power for the internal circuits and logic of controller 102.

In some examples, VINSENP/VINSENN/ISYS pins may be configured for sensing the input voltage (VIN) to controller 102 and/or the system current (ISYS). In some examples, PINALERT#/VR_HOT#/CAT_FAULT# pins may be utilized as protective features and/or status reporting pins that signal various fault conditions or operational status updates, such as over-temperature (VR_HOT) or catastrophic failures (CAT_FAULT).

In some examples, ENx/PGx/VR_READYx pins may enable inputs for the power stages and power good outputs indicating when each phase is ready or within regulation. SV_CLK, SV_DATA, SV_ALERT# pins may provide a serial interface for communication with the controller, for example, for software based configuration, monitoring, and/or alerting purposes. In some examples, SCL/SDA/SMALERT# pins may correspond to an inter-integrated circuit (I2C) bus interface, and/or other communication protocols for ICs. For example, SCL may be the clock line, SDA may encompass the data line, and SMALERT# may encompass an alert signal.

In some examples, controller 102 may be configured for single resistor selection via ADDR/BOOTCFG pin. Single resistor selection is the use of a single resistor to set the address (ADDR) or configuration (CFG) of a device, which may be used for electronic devices that communicate over a bus, such as I²C or SMBus. Utilizing a single resistor to set the address or configuration simplifies the hardware design. For example, instead of multiple jumpers or switches, one component is used, which may minimize space on the printed circuit board (PCB) and reduce manufacturing complexity. Moreover, in a multi-device system where several devices of the same kind may be present on the same bus, each device may use a different address. The single resistor selection allows for easy hardware-based address assignment by changing the resistance value, which may be read by the device at startup and correspond to a specific address. Similarly, if the resistor is used for configuration, changing its value may alter operational parameters of the device without reprogramming or using additional hardware.

Single resistor selection may reduce the overall component count in the system, which may lead to cost savings and enhanced reliability due to fewer potential points of failure. For example, in communication protocols like I²C, where each device on the bus may have a different address, the single resistor allows for easy adjustment of each device's address without changing the firmware or using dip-switches. Single resistor selection allows the device to work with different systems or in different modes, based on external hardware settings rather than software ones, which may be useful during the manufacturing process or in field configuration.

In the context of controller 102, utilizing a single resistor for address or configuration setting may enable the device to seamlessly integrate into a variety of systems with minimal adjustments. The single resistor for address and configuration settings allows for quick and easy customization of the controller's operation, which may be useful in complex systems with multiple controllers or in situations where the controller may be adapted to different operating conditions or functionalities.

In some examples, ADDR/BOOTCFG pin may be used to set the device address on the communication bus or to configure system 100 startup settings. In some examples, GND/DVDD pins may ground the digital power supply pins for the controller, providing reference and power for digital logic circuits.

In some examples SPS 104a-104d may include pins and interconnections for communicating with controller 102. In some examples, such communication interfaces may include, but are not limited to, pins shown as TMON/FAULT, PWM, IMON, and/or SW. In some examples, the TMON/FAULT pin may be purposed for temperature monitoring and fault detection, enabling proactive system protection. The PWM pin corresponds to the pulse width modulation signals used for controlling the power stages. The IMON pin provides real-time current monitoring feedback, useful for the regulation of power delivery. And the SW pin serves as a switch node, a junction in the power conversion process. Together, SPS 104 pins form an integrated network facilitating efficient signal transmission and system regulation.

For example, PWM1, PWM2 (Pulse Width Modulation) outputs from controller 102 to power stages 104a, 104b determine the pulse width modulation signals, controlling the timing and duration of the power transistors' switching events within individual power stages (e.g., SPS 104a). In some examples, IMON1, IMON2 correspond to current monitoring. IMON1, IMON2 outputs represent the monitored current flowing through the respective power stages (e.g. 104a, 104b). IMON1, IMON2 outputs may be used for feedback in a control loop (not shown) to regulate the current or for protection purposes.

In some examples, controller 102 may include TMONA which may be configured for temperature monitoring. As shown in FIG. 1, TMONA may be a shared terminal and used for temperature monitoring across multiple power stages (e.g., 104a, 104b). TMONA may collect temperature data to ensure that system 100 operates under or substantially under a temperature threshold corresponding to safe thermal conditions. For example, in some examples, TMONA circuitry may trigger a fault condition when an over-temperature event is detected.

Controller 102 may include pins VOUT1P, VOUT1N (Voltage Output Positive, Voltage output Negative). Voltage output pins provide the positive and negative terminals of the output voltage from SPS 104a, 104b. VOUT1P, VOUT1N pins provide the regulated voltage output that system 100 provides.

For example, PWM signals may control the switching power devices in SPS 104, which may convert the direct current (DC) input to a regulated output with the desired voltage and current characteristics. The IMON signals (e.g., IMON1, IMON2, IMON 3, and/or IMON4) may ensure that the amount of current flowing through SPS 104 is within the system 100 specifications and for making dynamic adjustments based on changing load.

As shown in FIG. 1, the sharing of the TMONA signal between different phases (e.g., SPS 104a, 104b) may offer an integrated temperature monitoring system that simplifies the thermal management by reducing the number of sensors, thereby streamlining the hardware design with minimal components. The VOUT1P and VOUT1N represent a differential pair, facilitating system 100's ability to minimize noise and ensure accurate voltage delivery, which may be used in high-precision applications or in environments with significant electrical interference.

As shown by pins PWM3 and PWM4, system 100 may include a modular, symmetrical protocol in the design of controller 102 that drives four outputs (i.e., SPS 104a, 104b, 104c, 104d). Such modular, symmetrical protocol, along with the shared architecture for other phases, may facilitate a uniform and modular approach to power management. Such dual or mirrored approach in the design of system 100 components (e.g., 102, 104) is advantageous for a variety of reasons.

For example, the symmetrical design allows for each phase, represented by PWM1/IMON1 through PWM4/IMON4, to follow the same or substantially the same architectural framework. Such modular configuration may facilitate scalability since additional phases may be added following the same architectural framework, which simplifies processes and ensures consistency for SPS 104a, 104b, 104c, 104d output. Moreover, modularity also aids in manufacturing and troubleshooting, as the same, or substantially the same, components and design considerations apply to each SPS 104a, 104b, 104c, 104d.

In some examples, employing such mirrored architecture across switching power supplies ensures that each phase may behave similarly, leading to steady performance when driving multiple outputs. Steady performance may be used in applications for accurate load balancing across phases. The mirrored configuration for the control of each phase ensures that the performance characteristics, such as efficiency, response time, and thermal management, may be uniform across the board, reducing the complexity of system-level optimization. The symmetry in the design inherently provides redundancy. If one phase were to fail, the other phases, being identical, may share the increased load, enhancing the system's overall reliability. For example, in applications where downtime is not permitted, such redundant design approach may ensure continuous operation, with the remaining phases compensating for the one that is out of service.

While the PWM signals control the timing and duty cycle for power delivery in each phase, the IMON signals provide a feedback mechanism for current monitoring. Such feedback monitoring may be used for closed-loop control and protection. The mirrored design provides that similar feedback control algorithms may be applied across all phases, streamlining the development of control firmware and software. Moreover, as shown in FIG. 1, temperature monitor TMONA, TMONB may have a shared connection to multiple phases, reflecting an integrated approach to temperature management across the controller system. The single-point monitoring simplifies the thermal management of the system, as the same cooling strategy may be applied uniformly.

In some examples, SW pins represent a switch node, for example, in a buck converter topology, which may be points where the high-frequency switching occurs. Having a symmetrical design for the SW pins across phases provides that the parasitic elements and switching characteristics may be uniform, which simplifies the layout considerations for electromagnetic compatibility and efficiency. Such switch node design also means that the ripple current and voltage may be easily managed and filtered, as the inductors and capacitors in the output filters may be identical, conserving the cost and space.

Controller 102 uniformly manages all phases due to the symmetry discussed above. Uniform management allows for a streamlined software and hardware interface, as the control algorithms do not need to be individually tailored for each phase. Such uniformity allows for a more intuitive and user-friendly GUI for device setup, as the settings for one phase may be applicable to the others. Doing so may reduce the complexity of system configuration and maintenance. Thus, the dual approach in the design of system 100 provides a steady and efficient method for managing multiple power stages in a power supply system. The uniformity and symmetry of the phases provide that the system is optimized for performance, ease of use, and reliability, all of which are highly advantageous in modern electronic applications.

In the examples herein, controller 102 and/or SPS 104a, 104b, 104c, 104d may include a number of processing units and/or CPUs. Use in any application involving processors and/or software: One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

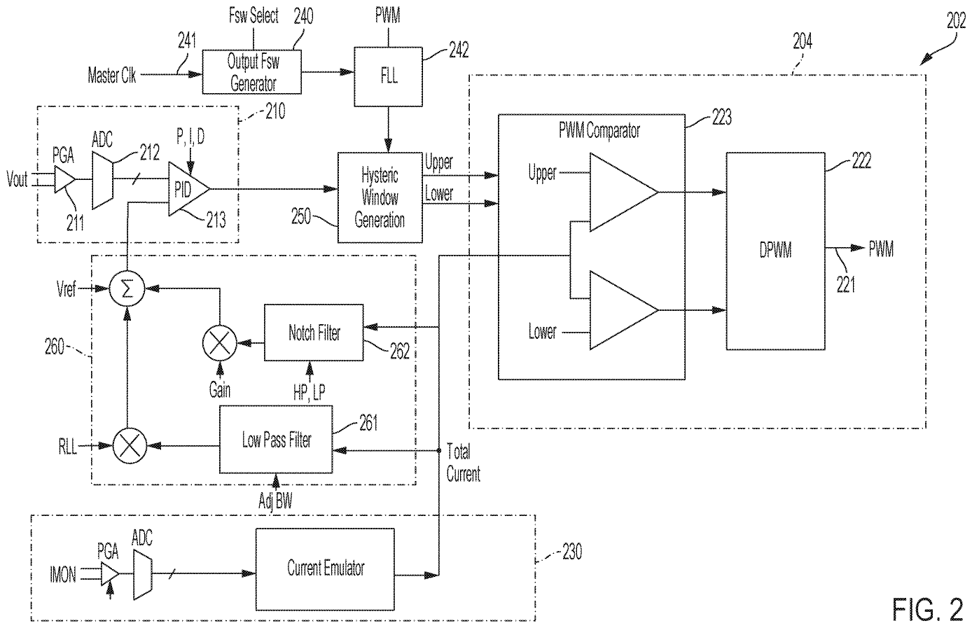

FIG. 2 depicts a control loop circuitry 202 (hereinafter “control loop 202”). Control loop 202 may include voltage regulator 210, pulse width circuitry 204, and current emulator 230. In some examples, control loop 202 may include a dual-loop for current and voltage regulation.

Control loop 202 may incorporate a master clock signal 241 that orchestrates Output Switching Frequency (FSW) Generation 240. FSW Generation 240 may facilitate determining the transistors' switching frequency in the power stages, and may be directly influenced by the FSW Select input, which may initiate the FSW Generation process. The generated FSW may not only drive the power transistors but may also be stabilized by the Frequency-Locked Loop (FLL) 242, which may incorporate a PWM output. FLL 242 may synchronize the oscillator's frequency, which may be derived from the master clock with an external reference signal, ensuring uniformity in the switching frequency throughout power switching operation. Such synchronization may maintain steady performance and efficiency of the power conversion process within control loop 202. FLL output signal may be fed to Hysteretic Window Generator (HWG) 250.

In some examples, HWG 250 may create a hysteretic band or window for current loop 202, where the power stage is turned on when the current drops below a lower threshold (e.g., lower) and off when the current exceeds an upper threshold (e.g., upper). Thus, in some examples, HWG 250 may establish a defined hysteretic band that controls the operational thresholds for the power stages within controller 102. As utilized herein, hysteretic band may be interchangeably referred to as the hysteretic window (i.e., upper and lower voltage thresholds). When the monitored current falls beneath the lower threshold, HWG 250 may prompt the power stage to activate, thereby increasing the current. Conversely, upon detecting that the current has surpassed the upper threshold, HWG 250 may deactivate the power stage, thus reducing the current flow. In some examples, the hysteretic band may facilitate phase-alignment in the multiphase signals in system 100.

Accordingly, such dynamic hysteretic band may provide a regulatory mechanism, operating in tandem with FLL 242 and Proportional-Integral-Derivative (PID) controller inputs via voltage regulator 210. FLL 242 may provide a stabilized frequency input to ensure steady switching intervals, while the PID input may allow for fine-tuned adjustments based on the hysteretic band's positioning. Such dual input strategy employed by HWG 250 may enable precise control over the current, contributing to controller 102's overall objective of maintaining a robust, stable and efficient power delivery system across multiple phases. The hysteretic band's implementation within control loop 202 exemplifies controller 102 sophisticated design, which is adept at handling the complexities of modern power management and distribution demands.

As shown in FIG. 2, control loop 202 may include a voltage regulator (VR) 210. In some examples, VR 210 may include Programmable Gain Amplifier (PGA) 211, Analog-to-Digital Converter (ADC) 212, and Proportional-Integral-Derivative (PID) controller 213. VR 210 may be configured for low latency in the feedback path, which may be used for real-time control systems where the response time may impact the system's performance. For example, in power supplies for sensitive satellite communication electronics, quick adjustments to the output voltage may maintain stability. Such low latency in the feedback path may provide rapid response to any changes in output voltage. For example, PGA 211 may adjust the gain of the signal to ensure ADC 212 may accurately read the voltage level regardless of the amplitude. ADC 212 may convert the analog voltage to a digital signal, which may be used for telemetry and for feedback in a control loop.

In some examples, VR 210 via PID controller 213 may be configured for dynamic voltage error control. For example, the “voltage error” may be the difference between the desired voltage set point and the actual Vout. PID controller 213 may process this error to adjust the control signals sent to the power stage. The “Proportional” part of PID controller 213 may respond to the current error, the “Integral” part may respond to the accumulation of past errors, and the “Derivative” part may respond to the rate of change of the error. By processing the error in these three ways, PID controller 213 may dynamically adjust the power output to quickly correct deviations from the desired voltage, ensuring tight regulation. As utilized herein dynamic voltage error control refers to system 100's ability to adapt to changing conditions on-the-fly. The PID algorithm of PID controller 213 allows for a dynamic response by automatically adjusting the control effort based on the error and a history. Such functionality may be used in power systems where load conditions may change rapidly, and the power supply may react just as quickly to prevent overshoot, undershoot, or oscillations in the output voltage.

In some examples PID controller 213 may process a feedback signal that is conditioned by an integrated filtering circuitry, filters 260. Filters 260 may tailor the feedback for optimal PID controller performance. Filters 260 may, in some examples, include Low Pass Filter (LPF) 261, which may attenuate high-frequency noise and transients, ensuring stable PID operation by allowing low-frequency content pertinent to the control loop. Additionally, Notch Filter 262 may be utilized to eliminate specific frequency bands known to be detrimental or irrelevant to the control process, thereby preventing resonance or other undesirable effects.

As shown in FIG. 2, the feedback signal of filters 260 may be derived from a current emulator 230, which may generate a signal indicative of the actual current, albeit in a synthesized form. Current emulator 230 may provide an estimated or synthesized representation of current information for control purposes and may not be used to replicate an inductor ripple waveform. The emulated current may be used in conjunction with digital control logic, filtering, and hysteretic threshold computation, without generating a synthetic ripple waveform corresponding to the inductor current. In some examples, current emulator 230 may employ an emulated current to enhance the precision and responsiveness of the power management process. Such approach may circumvent the issue of switching noise contamination within control loop 202, which may degrade the quality of the current signal and lead to inefficiencies and inaccuracies in power regulation. In some examples, current emulator 230 may provide full bandwidth current information meaning system 100 may accurately track current variations across a wide range of frequencies, ensuring robust performance even under rapidly changing loads or supply conditions.

Thus, incorporating emulated current into control loop 202 may facilitate real-time adjustments to power stage operations, optimizing performance, and minimizing the risk of overcurrent or undercurrent conditions that may harm system components or the load. By strategically bypassing the inherent noise of the power switching process, the controller 102 ensures that the decision-making process is based on clean, reliable data, thereby enhancing the overall stability of the power supply system. For example, such emulated current signal may offer a facsimile of the real current flow, which PID 213 may utilize for real-time corrective actions. By utilizing such emulation approach, system 100 may maintain a high degree of control fidelity without being affected by the inherent noise and variability of direct current measurements.

In some examples, low pass filter 261 and notch filter 262 aid in maintaining the integrity of the feedback loop. For example, low pass filter 261 and notch filter 262 ensure that PID controller 213 receives a clear and accurate representation of system 100 current state, which may be used for precise power regulation. The adjustable bandwidth (Adj BW, HP, LP) of low pass filter 261 and notch filter 262 further enhances system 100's adaptability, allowing for fine-tuning of control loop 202's responsiveness and stability under varying operational conditions.

In some examples, gain adjustment, RLL, may modify the amplitude of the signal. By adjusting the gain, the loop controller 202 may fine-tune the feedback signal to match the dynamic range of PID controller 213. Such matching ensures that loop controller 202 responds appropriately to various operating conditions without becoming overly sensitive to minor fluctuations or too sluggish to react to significant changes.

As shown, summation Circuit (Σ) is where the various feedback signals, including the output from the notch filter 262 and low pass filter 261, may be summed with a reference voltage (Vref). Vref may be the target voltage level for control loop 202, and the summing circuit may combine Vref with the feedback signals to determine an error between the actual and desired output. The error signal generated from this summation may be fed into the PID controller 213, which adjusts the power stage operation to correct the error. Thus, notch filter 262 and low pass filters 261, in conjunction with the gain adjustments and summing with Vref, may allow for tailored control across phases. Such tailored control facilitates refined and adaptive response to both steady-state and dynamic conditions, such as load changes, which may be used for high-efficiency power conversion in electronic devices.

In some examples, control loop 202 may include PWM circuitry 204. PWM circuitry 204 may include comparator 223 and Digital Pulse Width Modulator (DPWM) 222 which may generate a PWM signal 221. DPWM 222 may modulate the width of the pulses to control the power delivered to the load based on the commands from both control loops. In context of the operation of the dual loop control functionality, the voltage loop may maintain the output voltage by adjusting the duty cycle of the DPWM 222 based on the difference between the set point and the actual voltage. Simultaneously, the current loop may ensure that the output current does not exceed a certain level, safeguarding the system against overcurrent conditions.

In some examples, PID controller 213's inputs from filters 260 affect PWM circuitry 204, which may be responsible for modulating the PWM signals in accordance with PID controller 213 output. Such modulation may govern the switching behavior of the power stages within controller 102, aligning the output power delivery with system 100 real-time demands. The synergistic operation of the filtering circuitry, current emulation, PID controller, and PWM comparator underscores the comprehensive and dynamic nature of the control strategy employed by the controller 102.

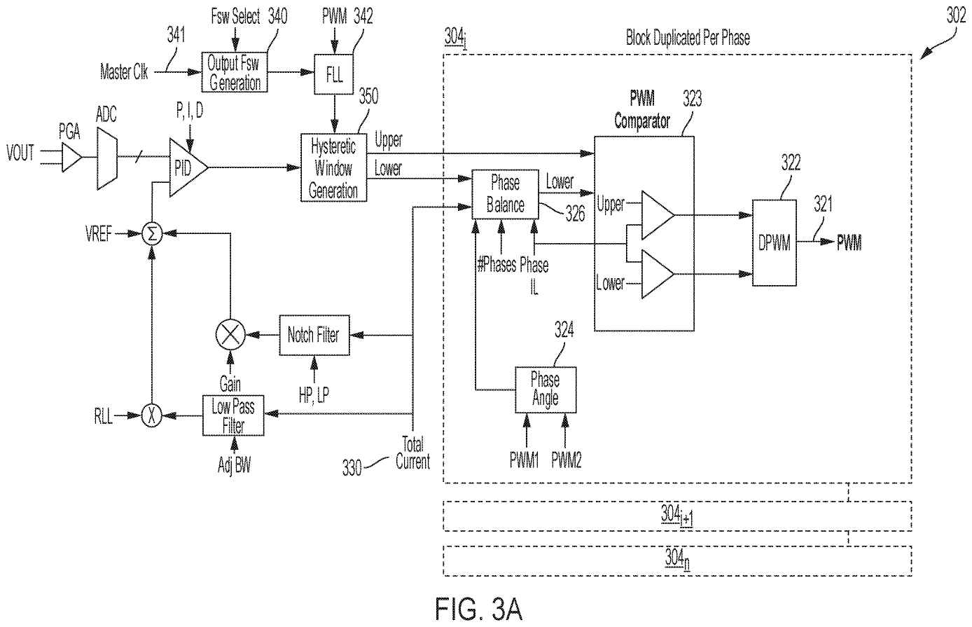

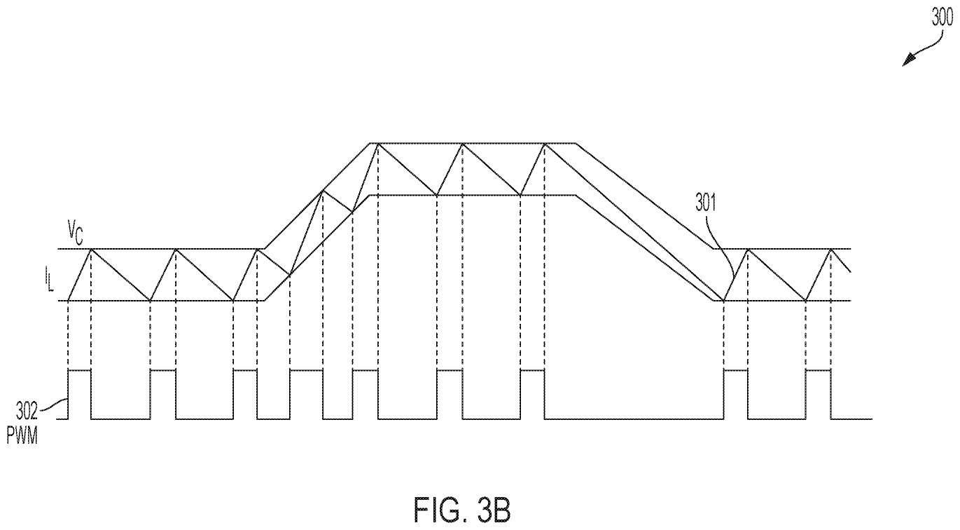

Referring now to FIGS. 3A-3B, in conjunction with FIGS. 1-2, FIG. 3A depicts a control loop 302. Control loop 302 is an example of control loop 202 in which similarly labeled parts and numbers correspond to similar features having similar functionality. In some examples, control loop 302 may include HWG 350, and load balance circuitry 304i-304n. Control loop 302 may provide enhanced multiphase capability.

FIG. 3B depicts a graph of Current Mode Hysteretic corresponding to HWG 350—showing control loop 302's PWM response with load transient. HWG 350 may allow for precise control and also phase alignment in the multi-phase system 100 by enabling Pulse Width modulation and frequency modulation. In this manner, control loop 302 may provide high speed control loop functionality. Graph 300 illustrates the relationship between the control voltage Vc, inductor current I_{L}, and the Pulse Width Modulation (PWM) signal in system 100. PWM signal shows the timing of the switches in the power circuit (e.g., SPS 104a, 104b, 104c, 104d). Such switches control the flow of current. The PWM signal dictates when the switch is ‘on’ (current flowing through the inductor) and ‘off’ (no current flow).

Waveform 301 above the PWM signal may represent the current through the inductor IL. When the PWM switch is ‘on’, the inductor current rises, storing energy in the magnetic field. When the switch is ‘off’, the current falls as the energy is delivered to the load. The slope of the inductor current waveform during these ‘on’ and ‘off’ periods may be determined by the input voltage and the characteristics of the inductor and the load. Overlaying the inductor current is a line representing the control voltage VC, which may set the reference levels for the hysteresis window generator 350. HWG 350 may turn the switch ‘on’ when the inductor current falls below a certain threshold (the lower edge of the window) and ‘off’ when the current exceeds the upper threshold. This creates a band, or window of operation for the current, preventing the current from oscillating and keeping the current within a specified range for stable operation.

In HWG 350, the capability to modulate frequency and PWM facilitates adjusting both the duty cycle and the frequency of the PWM signal, allowing for fine-tuned control over the power delivery for phase and current balance. In some examples, HWG 350 may include double edge modulation for adjusting the PWM signal at both the rising and falling edges, which may be used for reducing switching losses and improving efficiency. Controller 302 via HWG 350 may be configured for a single pole response with an output filter providing a fast response with minimal overshoot or ringing, which may be a characteristic of single-pole systems. HWG 350 thereby may include current control, which scales for multiphase operation. Accordingly, system 100 may control the current in multiphase applications. In this manner, control loop 302 may be configured for low latency, fast response, with low Zout for reacting quickly to changes. The low output impedance Zout, indicates a robust ability to maintain a stable output voltage despite load variations.

Thus, HWG 350 enables rapid response to load changes without using a distributed clock signal to synchronize the phases, thereby maintaining high efficiency and performance even in complex, multiphase power systems. As shown in FIG. 3A, load balance circuitry 304i may include DPWM 322, comparator 323, phase angle 324, and phase balance 326. PWM 304i may be duplicated per phase (n), where n is the number of phases. For example, in some examples, controller 302 may operate with 2, 3, or 4 phases and is capable to manage multiple power stages that share the load. Such sharing may lower ripple voltages and increase thermal performance as the heat generated by power conversion is distributed across multiple phases.

For example, incorporating phase balance 326 and phase angle 324 may allow for fine grain control over power stages (e.g., SPS 104a, 104b, 104c, 104d). Phase balance 326 and phase angle 324 may work in conjunction to ensure that power delivery is synchronized, balanced, and in-phase, which may be used for high-performance applications requiring precise power management and delivery. The integration of these features, including with the existing control mechanisms, may contribute to a comprehensive system that maintains optimal performance in a variety of operating conditions.

Phase balance 326 in loop controller 302 may ensure that the load is evenly distributed across all, or substantially all, phases in a multiphase power system (e.g., 100). An imbalance among phases may lead to inefficiencies, increased heat generation, and potential premature wear of components. Phase balance 326 may operate to correct such imbalances by dynamically adjusting the output of each phase to equalize the load. Thus, by monitoring and adjusting the balance, controller 102 may prevent a single phase from being overloaded, which may enhance system efficiency and longevity.

In some examples, phase angle 324 facilitates synchronization of the timing of the phases' power delivery. For example, in applications like motor control, precise phase angle adjustment via phase angle 324 may be used for the smooth operation of the motor. Adjusting the phase angle may aid in minimizing ripple current in the output and adjust the magnetic flux in applications such as transformers and inductors, thereby improving the overall power quality and reducing electromagnetic interference (EMI).

In some examples, comparator 323 facilitates the control component that may compare the output from phase balance 326 and phase angle 324 information with set thresholds to generate the PWM signal accurately. By adjusting, via DPWM 322, the PWM duty cycle in response to phase balance data and phase angle data, controller 102 ensures that individual power stages operate within designated parameters, contributing to the overall stability and performance system 100.

Phase balance data may refer to information that is generated by phase balance 326 that may be used for balancing load among multiple phases. The phase balance data may be generated based on one or more of total current, phase current information, phase angle information, hysteretic threshold information, or other control loop information. The phase balance data may be used to control one or more of switching behavior, pulse width modulation, current sharing, or load distribution for one or more phases.

Phase angle data may refer to information that is generated by phase angle 324 that may be used for controlling relative timing among multiple phases. The phase angle data may be based on one or more of phase position, phase offset, phase relationship, phase timing, phase error, or other information used to coordinate switching events of one or more phases. The phase angle may be used to control one or more of synchronization, switching-event timing, pulse width modulation, ripple reduction, or load-sharing behavior for one or more phases.

As shown in FIG. 3A, total current 330 input to phase balance 326 may ensure that system 100 not only monitors individual phase currents but also takes into account the total current draw. Such global view allows system 100 to make informed decisions about power allocation and phase adjustments.

In some examples, HWG 350 may advantageously operate without a distributed master clock signal (e.g., a non-clocked implementation). In contrast to a clocked system, relative phase timing between phases may not be imposed by a centrally distributed clock signal. Rather, the clock signal may be used for frequency stabilization and/or system timing. The relative timing for the multiple phases may be controlled using adaptive hysteretic threshold adjustment without using a distributed clock signal. Non-clocked may mean that the phases are not synchronized by a distributed clock between phases even though a local oscillator, free-running switch signal, or frequency lock mechanism may be used to control average switching frequency. Such method of control may rely on a “free-running” frequency generated by FSW generator 240. Thus, in system 100, the switching frequency may not be fixed but rather may vary depending on the load conditions and other factors. The control of this frequency may be accomplished through the use of a hysteresis window provided by HWG 350. For example, in free-running system 100, the absence of a distributed clock signal means there exist no mechanism for phase alignment or load balancing. Such mechanism may lead to inefficiencies, as the system may not optimally distribute power across the various phases. Lack of optimal power distribution may result in some switching power supply phases to become overburdened while others are under-utilized.

Accordingly, some examples achieve phase alignment via HWG 350 to define upper and lower thresholds for system 100's operation of the switching power supplies (e.g., 104a, 104b, 104c, 104d). For example, when the current or voltage exceeds such upper and lower thresholds, HWG 350 may adjust the operation of the power switches to bring the system back within the desired range. While Frequency-Locked Loop (FLL) 342 locks the average frequency to a desired target, an additional adjustment within the hysteresis window advantageously fine-tunes the phase relationship between the different power stages. The FLL 342 may regulate an average switching frequency without defining relative phase offsets between the multiple phases.

Accordingly, phase alignment for multiphase control in the non-clocked framework of system 100 is achieved by making minor adjustments to the phase of SPS 104 based on the hysteresis window output by HWG 350. Such adjustments facilitates current balancing across phases, ensuring each phase carries the share of the load evenly, thus improving overall system efficiency and performance.

In the context of system 100 overall, non-clocked phase adjustment and load balancing may represent an advancement in multiphase controller system (e.g., 100). Such non-clocked framework allows system 100 to maintain tight control over each phase of the power supply, ensuring that power is delivered where and when it is used, without the latency that can occur in clocked systems. The ability to perform these adjustments on-the-fly, responding in real time to the demands placed on the system, showcases a level of adaptability that may be used for modern power management systems. Non-clocked phase and current balancing enables system 100 to operate with high precision and efficiency for application in complex electronic systems.

Thus, in some examples, by connecting phases together at the output using a single control loop, controller 102, 202, 302 may synchronize phases to distribute power more evenly. In some examples, controller 102, 202, 302 operates with permitted permutations of multiphase. Such permutations may include (W+X+Y+Z<=4) facilitating a flexible configuration where controller 302 may manage four phases, with the ability to allocate these phases across the channels. This allows for various configurations such as: 4+0: All power may be delivered through a single phase, possibly for applications requiring high power on one channel; 3+1: Three phases may be used for one channel, and one phase for another, which may be useful for applications where one channel uses significantly more power than the others; 2+2: An even distribution of power across two channels, which may be beneficial for balancing load and thermal performance. Such capability also suggests that the controller may dynamically adjust the phase configuration based on the load or other system conditions, which would be an advanced feature demonstrating adaptability and efficiency.

For example, HWG 350 may influence the switching behavior of the power supply. HWG 350 sets two thresholds: an upper and a lower limit for a parameter, such as current or voltage. When the parameter exceeds the upper threshold, the system reacts, by turning off a switch. And HWG 350 will not turn the switch back on until the parameter falls below the lower threshold. Such switching creates a ‘window’ or dead zone where no action is taken, which helps to prevent system 100 from reacting to small fluctuations or noise, providing stability to the system and preventing rapid on-off cycling (i.e., chattering). In system 100, the hysteretic window ensures that individual phases engage or disengage, improving efficiency and reducing stress on the system's components.

As shown in FIG. 3A, total current 330 input into phase balance 326 may reflect the collective current being drawn by active phases (e.g., 104a-104d). Such input may be used for achieving a balanced power output, especially under varying load conditions. By monitoring the total current, the phase balance 326 may make informed decisions on how to distribute the load across each phase. If one phase is drawing more current than others, the system may reduce its load and increase the load on the less active phases, maintaining an equilibrium.

Lower threshold from Hysteretic Window Generation 350 input is part of the hysteretic window (or band) that defines the operational boundaries for the current control loop. As mentioned above, hysteretic window generation includes setting an upper and lower limit for the current level. When the current drops below the lower threshold, the system increases the drive to the power stage to boost the current. Conversely, when the current exceeds the upper threshold, the system reduces the drive. This input into the Phase balance 326 ensures that each phase contributes appropriately to the total current, adhering to the set hysteretic thresholds. It helps prevent any single phase from triggering a hysteretic response due to an unbalanced load.

The integration of total current monitoring and the lower threshold from hysteretic window generation provides that phase balance 326 plays a dual role by balancing the load based on the number of phases and the individual inductance of the respective phase, and keeping the total current within specified limits. Such level of control is advantageous in applications using precision power delivery and where the load might vary significantly over short periods, resulting in a responsive and adaptable control system.

In context of system 100, phase balance and phase angle 324, 326 contributes to system 100's overall stability and efficiency. For example, controller 102 may maintain a constant power output while responding dynamically to changes in load across multiple phases. Moreover, this integrated approach minimizes the risk of overcurrent conditions in any single phase, thereby protecting the system from potential damage and improving the reliability of the power supply. Intelligent balancing, considering total current and individual phase conditions, exemplifies the advanced nature of system 100, making system 100 well-suited for complex, high-stakes environments where power supply integrity is paramount.

Implementing HWG 350 in controller 302 is may be used for load sharing among the different phases and helps to maintain a balanced distribution of power. Such sharing may also aid in the reduction of ripple current when the phases are interleaved. For example, when a phase is operating near the upper threshold of a current limit, the hysteretic window may prevent triggering on and off rapidly due to minor variations in load or input voltage. Instead, another phase may pick up the additional load until the current drops below the lower threshold, ensuring robust operation.

HWG 350 is further advantageous for maintaining the stability by avoiding overreaction to transient conditions. Such stability ensures that power delivery is steady and reliable. In high-performance power systems (e.g., 100), utilizing high-speed control loops and high-resolution DPWM 322, the precise generation and management of the hysteretic window may be used for achieving the desired performance metrics.

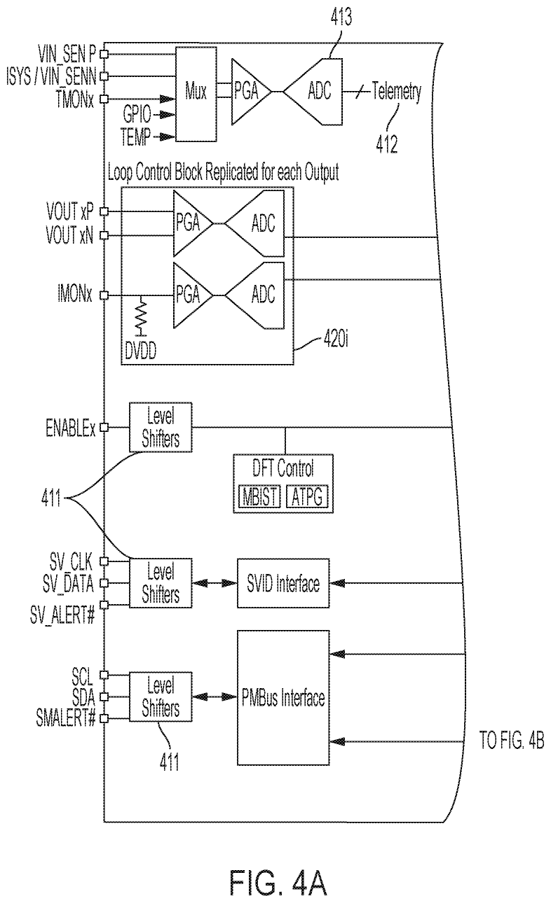

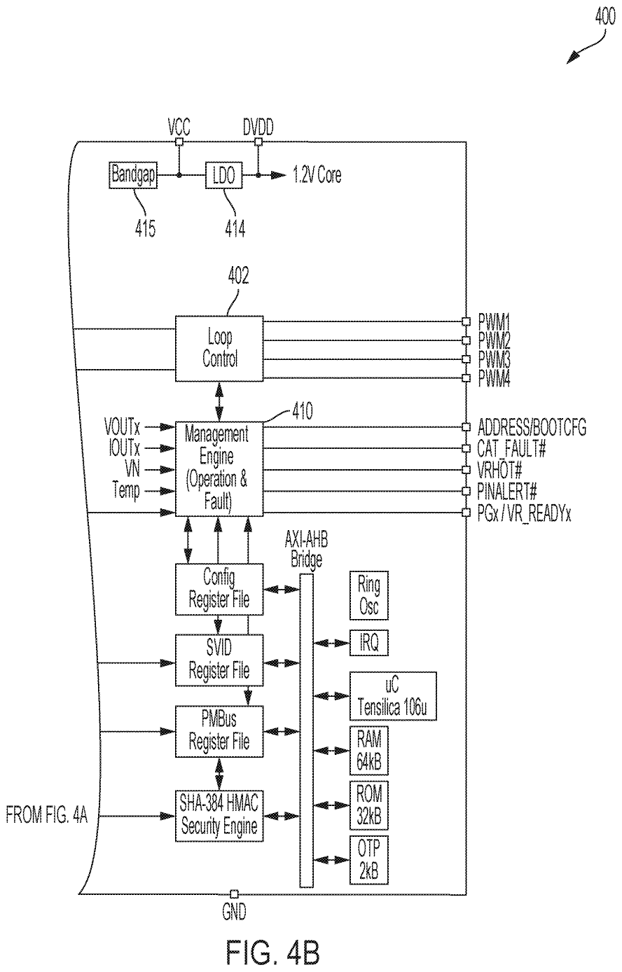

Referring now to FIGS. 4A and 4B in conjunction with FIGS. 1-3, FIGS. 4A and 4B depict Management Controller (MC) 400. In some examples, MC 400 may be implemented as a portion of controller 102, 202, 302. MC 400 may be used for high-performance applications for precision control and adaptability. For example, level shifters 411 facilitate interface with different voltage levels, and Digital System Management Engine (Operation & Fault) 410 (hereinafter “engine 410”) via control and telemetry, provided detailed monitoring and management for system 100.

As shown in FIGS. 4A and 4B, MC 400 may include state machines to manage the system 100 operation through various states, such as startup, normal operation, fault conditions, and shutdown. Loop Control 402 may adjust the input variables based on the feedback from the output. In some examples, MC 400 may include four separate dedicated control loops 420i for Vout Sensing, Control, and DPWM (Digital Pulse Width Modulation). Control loop 420i may be responsible for a specific task, which may allow for precise control over voltage regulation and power delivery. Such segregation of tasks helps in achieving high accuracy and fast response times. For example, system 100 may facilitate high speed, low latency of 50-100 MHz. The operation at these frequencies provides a very high-speed digital system, capable of processing signals and making control decisions quickly, reducing the overall latency of the system.

For example, in some examples, engine 410 may be capable of resolution at less than or equal to 312 ps. Engine 410, having such fine resolution, allows for accurate control of the power stages, which is advantageous for efficiency and performance in power supply units (e.g., SPS 104a, 104b, 104c, 104d). Such high resolution dynamic management of power and thermal loads by adjusting the pulse widths with great precision. In some examples, MC 400 includes microcontroller (μC) Tensilica 106u. The inclusion of a microcontroller (Tensilica 106u) facilitates a dedicated processor for handling complex tasks, for example, executing control algorithms, managing communication, and running housekeeping routines. The Tensilica 106u facilitates the agility of MC 400 (e.g., maintaining system 100 operational health by monitoring and managing the various system parameters and states).

In some examples, MC 400 may include an SHA-384 HMAC Security Engine for authentication and integrity checks. Telemetry 412 monitors and reports of system parameters (e.g., voltage levels, current draw, temperature, and the like). In some examples, ADC 413 may be coupled to telemetry 412. ADC 413 converts analog signals from various sensors into digital data that may be processed or logged by MC 400. Such data may be used for real-time monitoring, fault detection, and performance analysis and may allow for adaptive control strategies wherein system 100 may respond to changes in the operating environment or load conditions.

In some examples, low-dropout regulator (LDO) 414 may include a voltage regulator that may maintain a constant output voltage despite variations in the input voltage and load conditions. With the benefit of having a low dropout voltage (i.e., the difference between the input and output voltage where the regulator can still maintain the output voltage regulation), LDO 414 may provide clean and stable power with low noise, which may be used for reliable operation of the digital systems (e.g., 100). As shown, LDO 414 may provide a 1.2V core voltage, which may be used to power the core logic of MC 400. Such voltage level may be used for balancing performance and power efficiency.

For clarity, bandgap reference may be a voltage reference that provides a stable output voltage that is independent of temperature and supply voltage variations. The “bandgap” refers to the bandgap energy of semiconductors to generate a reference voltage. The stable voltage provided by the bandgap may be used for the accuracy of the ADCs and components within system 100 that use a steady reference point for correct operation. For example, for system 100, power regulation loops (e.g., control loop 202, 302) may ensure that the output voltages remain constant even if the temperature changes or the input voltage fluctuates.

Thus, MC 400 provides functions to system 100's stability and performance. Telemetry 412 allows for smart management of the system by providing data for the control algorithms to make decisions. LDO 414 ensures that the sensitive parts of the controller, like the microcontroller and digital circuits, receive a stable voltage. And bandgap reference 425 may be used for the precision of the entire system, as it sets the standard against which other voltages are measured or controlled.

The examples described above provide for a system for non-clocked phase alignment and load balancing within a digital quad controller, representing an advancement in the field of power electronics. The strategic implementation of Hysteresis Window Generation (HWG) in a multiphase control environment enables precise management of phase timing and load distribution without the constraints of a synchronized clock signal. This approach not only simplifies the system architecture by eliminating the master clock distribution scheme but also enhances performance by providing rapid, real-time adjustments to phase alignment for meeting the efficiency and stability of modern electronic devices. Accordingly, the examples herein provide optimal load balancing across phases, coupled with low-latency and high-bandwidth response characteristics, which ensures a stable output. Such features are paramount in applications ranging from sensitive computing devices to robust industrial machinery, where power supply integrity directly influences functionality and performance. System 100, therefore, sets a new standard for power management solutions, offering unmatched speed and flexibility in non-clocked IC systems and paving the way for more efficient, reliable, and adaptable electronic designs.

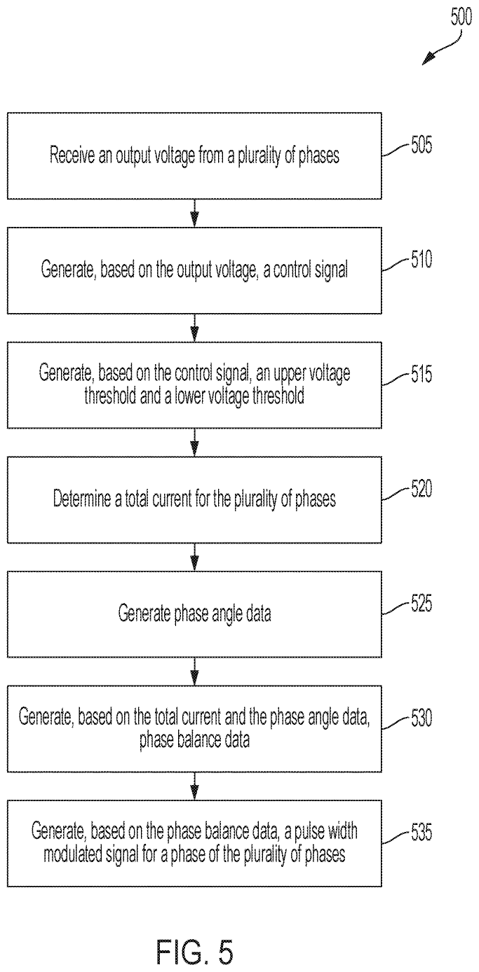

FIG. 5 illustrates a process flow of an example method 500 for a control loop circuit, in accordance with at least one example described in the present disclosure. The method 500 may be arranged in accordance with at least one example described in the present disclosure.

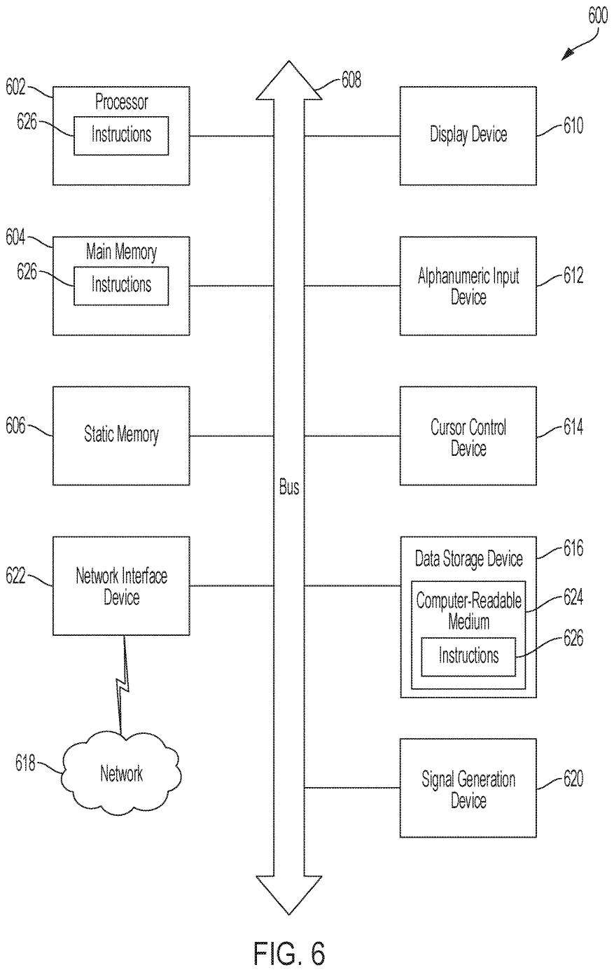

The method 500 may be performed by processing logic that may include hardware (circuitry, dedicated logic, etc.), software (such as is run on a computer system or a dedicated machine), or a combination of both, which processing logic may be included in the processing device 602 of FIG. 6, or another device, combination of devices, or systems.

The method 500 may begin at block 505 where the processing logic may receive an output voltage from a plurality of phases.

At block 510, the processing logic may generate, based on the output voltage, a control signal.

At block 515, the processing logic may generate, based on the control signal, an upper voltage threshold and a lower voltage threshold.

At block 520, the processing logic may determine a total current for the plurality of phases.

At block 525, the processing logic may generate phase angle data.

At block 530, the processing logic may generate, based on the total current and the phase angle data, phase balance data.

At block 535, the processing logic may generate, based on the phase balance data, a pulse width modulated signal for a phase of the plurality of phases.

In addition or alternatively, the processing logic may adjust a timing of switching events to maintain synchronization between the multiple phases without using a distributed clock signal. In addition or alternatively, the processing logic may distribute load across the multiple phases based on: the total current, and phase current for the multiple phases. In addition or alternatively, the processing logic may generate the upper voltage threshold and the lower voltage threshold based on an FLL signal. In addition or alternatively, the processing logic may generate the control signal based on a digitized output voltage. In addition or alternatively, the processing logic may adjust the control signal based on a voltage error. In addition or alternatively, the processing logic may generate an emulated current corresponding to current associated with the multiple phases.

Modifications, additions, or omissions may be made to the method 500 without departing from the scope of the present disclosure. For example, in some examples, the method 500 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

FIG. 6 illustrates a diagrammatic representation of a machine in the example form of a computing device 600 within which a set of instructions, for causing the machine to perform any one or more of the methods discussed herein, may be executed. The computing device 600 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative examples, the machine may be connected (e.g., networked) to other machines in a local area network (LAN), an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 600 includes a processing device (e.g., a processing device 602), a main memory 604 (e.g., read-only memory (ROM), flash memory, dynamic random access memory (DRAM) such as synchronous DRAM (SDRAM)), a static memory 606 (e.g., flash memory, static random access memory (SRAM)) and a data storage device 616, which communicate with each other via a bus 608.

Processing device 602 represents one or more general-purpose processing devices such as a microprocessor, central processing unit, or the like. More particularly, the processing device 602 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 602 may also include one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein.

The computing device 600 may further include a network interface device 622 which may communicate with a network 618. The computing device 600 also may include a display device 610 (e.g., a liquid crystal display (LCD) or a cathode ray tube (CRT)), an alphanumeric input device 612 (e.g., a keyboard), a cursor control device 614 (e.g., a mouse) and a signal generation device 620 (e.g., a speaker). In at least one example, the display device 610, the alphanumeric input device 612, and the cursor control device 614 may be combined into a single component or device (e.g., an LCD touch screen).

The data storage device 616 may include a computer-readable storage medium 624 on which is stored one or more sets of instructions 626 embodying any one or more of the methods or functions described herein. The instructions 626 may also reside, completely or at least partially, within the main memory 604 and/or within the processing device 602 during execution thereof by the computing device 600, the main memory 604 and the processing device 602 also constituting computer-readable media. The instructions may further be transmitted or received over a network 618 via the network interface device 622.

While the computer-readable storage medium 624 is shown in an example to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

The examples described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “example” in the singular is not intended to imply any limitation on the scope of the claims set forth below. Multiple examples may be set forth according to the limitations of the multiple claims issuing from this disclosure, and such claims accordingly define the example(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred examples, it is to be understood that such detail is solely for that purpose and that the disclosure is not limited to the expressly disclosed examples, but, on the contrary, is intended to cover modifications and equivalent arrangements that are within the spirit and scope of the appended claims. For example, it is to be understood that the present disclosure contemplates that, to the extent possible, one or more features of any example can be combined with one or more features of any other example.

What is claimed is:

1. A controller, comprising:
a voltage regulator operable to generate a control signal;
a hysteretic window generator operable to generate, based on the control signal, an upper voltage threshold and a lower voltage threshold;
a phase angle operable to generate phase angle data;
a phase balance operable to receive a total current for a plurality of phases and generate, based on the total current and the phase angle data, phase balance data; and
a pulse width modulator operable to generate, based on the phase balance data, a pulse width modulated signal for a phase of the plurality of phases,
wherein relative timing for the plurality of phases is controlled using adaptive hysteretic threshold adjustment without using a distributed clock signal.

2. The controller of claim 1, wherein the phase angle is further operable to adjust a timing of switching events to maintain synchronization between the plurality of phases without using a distributed clock signal.

3. The controller of claim 1, wherein the phase balance is operable to distribute load across the plurality of phases based on: the total current, and phase current for the plurality of phases.

4. The controller of claim 1, further comprising a master clock coupled to a frequency-locked loop (FLL), wherein the FLL outputs an FLL signal to the hysteretic window generator, and wherein the hysteretic window generator is operable to generate the upper voltage threshold and the lower voltage threshold based on the FLL signal, and wherein the FLL regulates an average switching frequency of the controller without defining relative phase offsets for the plurality of phases.

5. The controller of claim 1, wherein the voltage regulator comprises:
a programmable gain amplifier (PGA) operable to receive an output voltage and output an amplified output voltage;
an analog-to-digital converter (ADC) operable to digitize the amplified output voltage to generate a digitized output voltage; and
a proportional-integral-derivative (PID) controller operable to generate the control signal based on the digitized output voltage.

6. The controller of claim 5, wherein the PID controller is operable to adjust the control signal based on a voltage error.

7. The controller of claim 1, further comprising a current emulator operable to generate an emulated current corresponding to current associated with the plurality of phases.

8. The controller of claim 7, further comprising one or more of:
a low-pass filter operable to attenuate high-frequency noise of the emulated current; or
a notch filter operable to attenuate a selected frequency of the emulated current.

9. The controller of claim 1, wherein the phase balance is further operable to:
receive the lower voltage threshold from the hysteretic window generator; and
generate the phase balance data further based on the lower voltage threshold.

10. The controller of claim 1, wherein the pulse width modulator comprises:
a digital pulse width modulator (DPWM); and
a comparator operable to generate the pulse width modulated signal based on the phase balance data.

11. A system, comprising:
a plurality of phases operable to supply current to a load; and
a controller comprising:
a voltage regulator operable to generate a control signal;
a hysteretic window generator operable to generate, based on the control signal, an upper voltage threshold and a lower voltage threshold;
a phase angle operable to generate phase angle data;
a phase balance operable to receive a total current for the plurality of phases and generate, based on the total current and the phase angle data, phase balance data; and
a pulse width modulator operable to generate, based on the phase balance data, a pulse width modulated signal for a phase of the plurality of phases.

12. The system of claim 11, wherein the phase angle is further operable to adjust a timing of switching events to maintain synchronization between the plurality of phases without using a distributed clock signal.

13. The system of claim 11, wherein the phase balance is operable to distribute load across the plurality of phases based on: the total current, and phase current for the plurality of phases.

14. A method, comprising:
receiving an output voltage from a plurality of phases;
generating, based on the output voltage, a control signal;
generating, based on the control signal, an upper voltage threshold and a lower voltage threshold;
determining a total current for the plurality of phases;
generating phase angle data;
generating, based on the total current and the phase angle data, phase balance data; and
generating, based on the phase balance data, a pulse width modulated signal for a phase of the plurality of phases.

15. The method of claim 14, further comprising:
adjusting a timing of switching events to maintain synchronization between the plurality of phases without using a distributed clock signal.

16. The method of claim 14, further comprising:
distributing load across the plurality of phases based on: the total current, and phase current for the plurality of phases.

17. The method of claim 14, further comprising:
generating the upper voltage threshold and the lower voltage threshold based on a frequency-locked loop (FLL) signal.

18. The method of claim 14, further comprising:
generating the control signal based on a digitized output voltage.

19. The method of claim 14, further comprising:
adjusting the control signal based on a voltage error.

20. The method of claim 14, further comprising:
generating an emulated current corresponding to current associated with the plurality of phases.
